(19) United States
(12) Patent Application Publication
(10) Pub. No.: US 2025/0089290 A1
(43) Pub. Date: Mar. 13, 2025

(54) CURRENT COLLAPSE REDUCTION USING ALUMINUM NITRIDE BACK BARRIER AND IN-SITU TWO-STEP PASSIVATION

(71) Applicant: Soctera, Inc., Ithaca, NY (US)

(72) Inventors: Austin Hickman, Ithaca, NY (US); Debdeep Jena, Ithaca, NY (US)

(73) Assignee: Soctera, Inc., Ithaca, NY (US)

(21) Appl. No.: 18/882,236

(22) Filed: Sep. 11, 2024

Related U.S. Application Data
(60) Provisional application No. 63/538,233, filed on Sep. 13, 2023.
(60) Provisional application No. 63/553,521, filed on Feb. 14, 2024.
(60) Provisional application No. 63/678,916, filed on Aug. 2, 2024.

(51) Int. Cl. H01L 29/778; H01L 21/02; H01L 21/283; H01L 23/29; H01L 23/31; H01L 29/06; H01L 29/20; H01L 29/417; H01L 29/423; H01L 29/66

(52) U.S. Cl. CPC H10D 30/475; H01L 21/02293; H01L 23/3171; H01L 23/3192; H10D 30/015; H10D 62/103; H10D 64/518; H01L 21/283; H01L 23/291; H10D 62/8503; H10D 64/254

(57) ABSTRACT

Device structures and methods for reducing current collapse in high electron mobility transistors (HEMT) using aluminum nitride back barrier and in-situ two-step passivation are disclosed. In one aspect, the HEMT includes a back barrier layer including Al and N on a substrate, a channel layer including Ga and N on the back barrier layer, an AlₓGa₁₋ₓN layer on the channel layer, a first passivation layer on the AlₓGa₁₋ₓN layer, source and drain ohmic contacts, a T-shaped gate electrode at a location on a surface between the drain ohmic contact and the source ohmic contact, and a second passivation layer on the first passivation layer covering the surface and the T-shaped gate electrode.

### CROSS-REFERENCES TO RELATED APPLICATIONS

This application claims priority to U.S. Provisional Patent Application No. 63/538,233 filed Sep. 13, 2023, U.S. Provisional Patent Application No. 63/553,521 filed Feb. 14, 2024, and U.S. Provisional Patent Application No. 63/678,916 filed Aug. 2, 2024, the disclosures of which are hereby incorporated by reference in their entireties for all purposes.

### BACKGROUND OF THE INVENTION

The present disclosure generally relates to compound semiconductor devices and more particularly to a high power gallium nitride (GaN)-based compound semiconductor device used in radio frequency (RF) amplifiers. A GaN high electron mobility transistor (HEMT) can offer relatively high operating frequencies and high operational efficiencies when used in RF amplifiers. GaN amplifiers can operate at relatively high power densities (e.g., power densities greater than 1 W/mm) at Gigahertz frequencies.

Despite the progress made in device structures and fabrication methods for GaN HEMTs, there is a need in the art for improved methods and systems related to GaN HEMT device structures and fabrication methods.

### SUMMARY OF THE INVENTION

In accordance with various aspects of the present disclosure, embodiments of the present disclosure relate to current collapse reduction using aluminum nitride back barrier and in-situ two-step passivation fabrication methods. In particular, embodiments of the present invention provide solutions related to the presence of trap states in GaN HEMTs, which can cause performance degradations, e.g., the traps can cause a phenomenon known as current-collapse, and reduce the maximum available power density of the GaN HEMT by as much as 90%. As described herein, embodiments of the present invention control the trap states in GaN HEMTs in order to improve performance and operational efficiencies of these RF amplifiers.

According to an embodiment of the present invention, a high electron mobility transistor (HEMT) device is provided. The HEMT device includes a back barrier layer including Al and N on a substrate, a channel layer including Ga and N on the back barrier layer, an AlₓGa₁₋ₓN layer on the channel layer, where x is in a range of 0.2 to 1, and where the AlₓGa₁₋ₓN layer and the channel layer are arranged to form a two-dimensional electron gas (2DEG) channel at an interface of the AlₓGa₁₋ₓN layer and the channel layer, a first passivation layer on the AlₓGa₁₋ₓN layer and having a composition Al_{y}Si_{1-y}N, where y is in a range of 0 to 1, a drain ohmic contact coupled to the channel layer at a first end of the 2DEG channel, and a source ohmic contact coupled to the channel layer at a second end of the 2DEG channel opposite the first end of the channel. The HEMT device also includes a T-shaped gate electrode at a location on a surface between the drain ohmic contact and the source ohmic contact, the T-shaped gate electrode including a neck portion that extends a first distance above the surface to a head portion of the T-shaped gate electrode, a gate electrode recess in an uppermost surface of the head portion of the T-shaped gate electrode, a second passivation layer on the first passivation layer and continuously extending from an upper surface of the drain ohmic contact to an upper surface of the source ohmic contact to cover the surface and to cover the T-shaped gate electrode including into the gate electrode recess, and a passivation layer recess in an upper surface of the second passivation layer above the gate electrode recess, where the passivation layer recess has a passivation layer recess shape that conforms to a shape of the gate electrode recess.

According to another embodiment of the present invention, a method of fabricating a high electron mobility transistor (HEMT) device is provided. The method includes providing a substrate, epitaxially growing, in an epitaxial growth system, a back barrier layer including Al and N on the substrate, epitaxially growing, in the epitaxial growth system, a channel layer including Ga and N on the back barrier layer, epitaxially growing, in the epitaxial growth system, an AlₓGa₁₋ₓN layer on the channel layer, where x is in a range of 0.2 to 1, and where the AlₓGa₁₋ₓN layer and the channel layer are arranged to form a two-dimensional electron gas (2DEG) channel at an interface of the AlₓGa₁₋ₓN layer and the channel layer. The method also includes depositing a first passivation layer on the AlₓGa₁₋ₓN layer, where the first passivation layer is deposited in-situ in the epitaxial growth system directly after the epitaxial growth of the AlₓGa₁₋ₓN layer and prior to air exposure, where the first passivation layer has a composition Al_{y}Si_{1-y}N, and where y is in a range of 0 to 1, forming device isolation regions, forming a drain ohmic contact coupled to the channel layer at a first end of the 2DEG channel, and forming a source ohmic contact coupled the channel layer at a second end of the 2DEG channel opposite the first end of the channel, forming a T-shaped gate electrode at a location on a surface between the drain ohmic contact and the source ohmic contact, where the T-shaped gate electrode contacts the AlₓGa₁₋ₓN layer, where the T-shaped gate electrode includes a neck portion that extends a first distance above the surface to a head portion of the T-shaped gate electrode, and depositing a second passivation layer on the first passivation layer.

Example 1: A high electron mobility transistor (HEMT) comprising: a back barrier layer including Al and N on a substrate; a channel layer including Ga and N on the back barrier layer; an AlxGa1-xN layer on the channel layer, wherein x is in a range of 0.2 to 1, and wherein the AlxGa1-xN layer and the channel layer are arranged to form a two-dimensional electron gas (2DEG) channel at an interface of the AlxGa1-xN layer and the channel layer; a first passivation layer on the AlxGa1-xN layer and having a composition AlySi1-yN, wherein y is in a range of 0 to 1; a drain ohmic contact coupled to the channel layer at a first end of the 2DEG channel; a source ohmic contact coupled to the channel layer at a second end of the 2DEG channel opposite the first end of the channel; a T-shaped gate electrode at a location on a surface between the drain ohmic contact and the source ohmic contact, the T-shaped gate electrode including a neck portion that extends a first distance above the surface to a head portion of the T-shaped gate electrode; a gate electrode recess in an uppermost surface of the head portion of the T-shaped gate electrode; a second passivation layer on the first passivation layer and continuously extending from an upper surface of the drain ohmic contact to an upper surface of the source ohmic contact to cover the surface and to cover the T-shaped gate electrode including into the gate electrode recess; and a passivation layer recess in an upper surface of the second passivation layer above the gate electrode recess, the passivation layer recess having a passivation layer recess shape that conforms to a shape of the gate electrode recess.

Example 2: The HEMT of Example 1, further comprising a recessed region through the first passivation layer, wherein the recessed region is used to form a gate contact to the AlxGa1-xN layer.

Example 3: The HEMT of Example 1, wherein the channel layer has a thickness less than 500 nm.

Example 4: A method of fabricating a high electron mobility transistor (HEMT), the method comprising: providing a substrate; epitaxially growing, in an epitaxial growth system, a back barrier layer including Al and N on the substrate; epitaxially growing, in the epitaxial growth system, a channel layer including Ga and N on the back barrier layer; epitaxially growing, in the epitaxial growth system, an AlxGa1-xN layer on the channel layer, wherein x is in a range of 0.2 to 1, and wherein the AlxGa1-xN layer and the channel layer are arranged to form a two-dimensional electron gas (2DEG) channel at an interface of the AlxGa1-xN layer and the channel layer; depositing a first passivation layer on the AlxGa1-xN layer, wherein the first passivation layer is deposited in-situ in the epitaxial growth system directly after the epitaxial growth of the AlxGa1-xN layer and prior to air exposure, wherein the first passivation layer has a composition AlySi1-yN, and wherein y is in a range of 0 to 1; forming device isolation regions; forming a drain ohmic contact coupled to the channel layer at a first end of the 2DEG channel; forming a source ohmic contact coupled the channel layer at a second end of the 2DEG channel opposite the first end of the channel; forming a T-shaped gate electrode at a location on a surface between the drain ohmic contact and the source ohmic contact, the T-shaped gate electrode contacting the AlxGa1-xN layer, wherein the T-shaped gate electrode includes a neck portion that extends a first distance above the surface to a head portion of the T-shaped gate electrode; and depositing a second passivation layer on the first passivation layer.

Example 5: The method of Example 4, wherein depositing the second passivation layer is performed using a low pressure chemical vapor deposition (LPCVD) process.

Example 6: The method of Example 4, wherein depositing the second passivation layer is performed using a plasma enhanced chemical vapor deposition (PECVD) process.

Example 7: The method of Example 4, wherein the second passivation layer comprises silicon nitride (SiN).

Example 8: The method of Example 4, wherein the second passivation layer continuously extends from an upper surface of the drain ohmic contact to an upper surface of the source ohmic contact to cover the surface and to cover the T-shaped gate electrode including into a gate electrode recess.

Example 9: The method of Example 4, wherein the second passivation layer comprises a passivation layer recess having a passivation layer recess shape that conforms to a shape of a gate electrode recess.

Example 10: The method of Example 4, wherein forming a drain and a source ohmic contact comprises: depositing drain and source metals on a surface of the AlxGa1-xN layer; and annealing to fuse the drain and source metals through the AlxGa1-xN layer to form contacts to the 2DEG channel.

Example 11: The method of Example 4, wherein forming a drain and source ohmic contact comprises: forming drain and source recessed regions by dry etching; and growing n-type doped GaN to form contacts to the 2DEG channel.

Example 12: A method of fabricating a gallium nitride (GaN) based high electron mobility transistor (HEMT), the method comprising: providing a substrate; epitaxially growing, in an epitaxial growth system, a back barrier layer including Al and N on the substrate; epitaxially growing, in the epitaxial growth system, a channel layer including Ga and N on the back barrier layer; epitaxially growing, in the epitaxial growth system, an AlxGa1-xN layer on the channel layer, wherein x is in a range of 0.2 to 1, and wherein the AlxGa1-xN layer and the channel layer are arranged to form a two-dimensional electron gas (2DEG) channel at an interface of the AlxGa1-xN layer and the channel layer; depositing a first passivation layer on the AlxGa1-xN layer, wherein the first passivation layer is deposited in-situ in the epitaxial growth system directly after the epitaxial growth of the AlxGa1-xN layer and prior to air exposure, wherein the first passivation layer has a composition AlySi1-yN, and wherein y is in a range of 0 to 1; depositing a second passivation layer on the first passivation layer; forming device isolation regions; forming a drain ohmic contact recessed into the channel layer at a first end of the 2DEG channel; forming a source ohmic contact recessed into the channel layer at a second end of the 2DEG channel opposite the first end of the channel; and forming a T-shaped gate electrode at a location on a surface between the drain ohmic contact and the source ohmic contact, the T-shaped gate electrode contacting the AlxGa1-xN layer, wherein the T-shaped gate electrode includes a neck portion that extends a first distance above the surface to a head portion of the T-shaped gate electrode.

Example 13: A high electron mobility transistor (HEMT) comprising: a back barrier layer including Al and N on a substrate; a channel layer including Ga and N on the back barrier layer; an AlxGa1-xN layer on the channel layer, wherein x is in a range of 0.2 to 1, and wherein the AlxGa1-xN layer and the channel layer are arranged to form a two-dimensional electron gas (2DEG) channel at an interface of the AlxGa1-xN layer and the channel layer; a first passivation layer on the AlxGa1-xN layer, wherein the first passivation layer has a composition AlzGa1-zN, wherein z is in a range of 0 to 1, wherein a thickness of the first passivation layer is between about 1 nm and about 5 nm; a drain ohmic contact coupled to the channel layer at a first end of the 2DEG channel; a source ohmic contact coupled to the channel layer at a second end of the 2DEG channel opposite the first end of the channel; a T-shaped gate electrode at a location on a surface between the drain ohmic contact and the source ohmic contact, the T-shaped gate electrode including a neck portion that extends a first distance above the surface to a head portion of the T-shaped gate electrode; a gate electrode recess in an uppermost surface of the head portion of the T-shaped gate electrode; a second passivation layer on the first passivation layer and continuously extending from an upper surface of the drain ohmic contact to an upper surface of the source ohmic contact to cover the surface and to cover the T-shaped gate electrode including into the gate electrode recess; and a passivation layer recess in an upper surface of the second passivation layer above the gate electrode recess, the passivation layer recess having a passivation layer recess shape that conforms to a shape of the gate electrode recess.

Example 14: A method of fabricating a high electron mobility transistor (HEMT), the method comprising: providing a substrate; epitaxially growing, in an epitaxial growth system, a back barrier layer including Al and N on the substrate; epitaxially growing, in the epitaxial growth system, a channel layer including Ga and N on the back barrier layer; epitaxially growing, in the epitaxial growth system, an AlxGa1-xN layer on the channel layer, wherein x is in a range of 0.2 to 1, and wherein the AlxGa1-xN layer and the channel layer are arranged to form a two-dimensional electron gas (2DEG) channel at an interface of the AlxGa1-xN layer and the channel layer; depositing a first passivation layer on the AlxGa1-xN layer, wherein the first passivation layer is deposited in-situ in the epitaxial growth system directly after the epitaxial growth of the AlxGa1-xN layer and prior to air exposure, wherein the first passivation layer has a composition AlzGa1-zN, and wherein a thickness of the first passivation layer is between about 1 nm and about 5 nm; depositing a temporary passivation layer on the first passivation layer, wherein the temporary passivation layer is deposited in-situ in the epitaxial growth system directly after the epitaxial growth of the first passivation layer and prior to air exposure, wherein the temporary passivation layer has a composition AlySi1-yN, and wherein y is in a range of 0 to 1; removing the temporary passivation layer directly prior to fabricating the HEMT; forming device isolation regions; forming a drain ohmic contact coupled to the channel layer at a first end of the 2DEG channel; forming a source ohmic contact coupled the channel layer at a second end of the 2DEG channel opposite the first end of the channel; forming a T-shaped gate electrode at a location on a surface between the drain ohmic contact and the source ohmic contact, the T-shaped gate electrode contacting the AlxGa1-xN layer, wherein the T-shaped gate electrode includes a neck portion that extends a first distance above the surface to a head portion of the T-shaped gate electrode; and depositing a second passivation layer on the first passivation layer.

Example 15: A high electron mobility transistor (HEMT) comprising: a back barrier layer including Al and N on a substrate; a channel layer including Ga and N on the back barrier layer; an interlayer on the channel layer, wherein the interlayer has a composition AlwGa1-wN, wherein w is in a range of 0.2 and 1, and wherein the interlayer and the channel layer are arranged to form a two-dimensional electron gas (2DEG) channel at an interface of the interlayer and the channel layer; an AlxGa1-xN barrier layer on the interlayer, wherein x is in a range of 0.2 to 1; a first passivation layer on the AlxGa1-xN barrier layer, wherein the first passivation layer has a composition AlzGa1-zN, wherein z is in a range of 0 to 1, wherein a thickness of the first passivation layer is between about 0.5 nm and about 5 nm; an in-situ passivation layer on the first passivation layer, wherein the in-situ passivation layer has a composition AlySi1-yN, wherein y is in a range of 0 to 1, wherein a thickness of the in-situ passivation layer is between about 0 nm and about 20 nm; a drain ohmic contact coupled to the channel layer at a first end of the 2DEG channel; a source ohmic contact coupled to the channel layer at a second end of the 2DEG channel opposite the first end of the channel; a T-shaped gate electrode at a location on a surface between the drain ohmic contact and the source ohmic contact, the T-shaped gate electrode including a neck portion that extends a first distance above the surface to a head portion of the T-shaped gate electrode; and a second passivation layer on the in-situ passivation layer and continuously extending from an upper surface of the drain ohmic contact to an upper surface of the source ohmic contact to cover the surface and to cover a bottom surface of the head portion of the T-shaped gate electrode and the neck portion.

Example 16: The HEMT of Example 15, further comprising a recessed region through the in-situ passivation layer, wherein the recessed region is used to form a gate contact to the first passivation layer.

Example 17: The HEMT of Example 15, further comprising a third passivation layer that extends continuously from the upper surface of the drain ohmic contact to the upper surface of the source ohmic contact to cover the surface and to cover the T-shaped gate electrode.

Example 18: The HEMT of Example 17, further comprising: a gate electrode recess in an uppermost surface of the head portion of the T-shaped gate electrode; and a passivation layer recess in an upper surface of the third passivation layer above the gate electrode recess, the passivation layer recess having a passivation layer recess shape that conforms to a shape of the gate electrode recess.

Example 19: The HEMT of Example 17, further comprising a source-connected metal field plate deposited on a top surface of the third passivation layer and located between a source edge of the T-shaped gate electrode and an edge of the drain ohmic contact.

Example 20: A high electron mobility transistor (HEMT) comprising: a back barrier layer including Al and N on a substrate; a channel layer including Ga and N on the back barrier layer; an interlayer on the channel layer, wherein the interlayer has a composition AlwGa1-wN, wherein w is in a range of 0.2 and 1, and wherein the interlayer and the channel layer are arranged to form a two-dimensional electron gas (2DEG) channel at an interface of the interlayer and the channel layer; an AlxGa1-xN barrier layer on the interlayer, wherein x is in a range of 0.2 to 1; a first passivation layer on the AlxGa1-xN barrier layer, wherein the first passivation layer has a composition AlzGa1-zN, wherein z is in a range of 0 to 1, wherein a thickness of the first passivation layer is between about 0.5 nm and about 5 nm; an in-situ passivation layer on the first passivation layer, wherein the in-situ passivation layer has a composition AlySi1-yN, wherein y is in a range of 0 to 1, wherein a thickness of the in-situ passivation layer is between about 0 nm and about 20 nm; a drain ohmic contact coupled to the channel layer at a first end of the 2DEG channel; a source ohmic contact coupled to the channel layer at a second end of the 2DEG channel opposite the first end of the channel; a T-shaped gate electrode at a location on a surface between the drain ohmic contact and the source ohmic contact, the T-shaped gate electrode including a neck portion that extends a first distance above the surface to a head portion of the T-shaped gate electrode; and a second passivation layer on the in-situ passivation layer and continuously extending from an upper surface of the drain ohmic contact to an upper surface of the source ohmic contact to cover the surface and to cover the T-shaped gate electrode.

Example 21: The HEMT of Example 20, further comprising: a gate electrode recess in an uppermost surface of the head portion of the T-shaped gate electrode; and a passivation layer recess in an upper surface of the second passivation layer above the gate electrode recess, the passivation layer recess having a passivation layer recess shape that conforms to a shape of the gate electrode recess.

Example 22: The HEMT of Example 20, further comprising a recessed region through the in-situ passivation layer, wherein the recessed region is used to form a gate contact to the first passivation layer.

Example 23: The HEMT of Example 20, further comprising a source-connected metal field plate deposited on a top surface of the second passivation layer and located between a source edge of the T-shaped gate electrode and an edge of the drain ohmic contact.

Example 24: A method of fabricating a gallium nitride (GaN) based high electron mobility transistor (HEMT), the method comprising: providing a substrate; epitaxially growing, in an epitaxial growth system, a back barrier layer including Al and N on the substrate; epitaxially growing, in the epitaxial growth system, a channel layer including Ga and N on the back barrier layer; epitaxially growing, in the epitaxial growth system, an interlayer on the channel layer, wherein the interlayer has a composition AlwGa1-wN, wherein w is in a range of 0.2 and 1, and wherein the interlayer and the channel layer are arranged to form a two-dimensional electron gas (2DEG) channel at an interface of the interlayer and the channel layer; epitaxially growing, in the epitaxial growth system, an AlxGa1-xN barrier layer on the interlayer, wherein x is in a range of 0.2 to 1; epitaxially growing, in the epitaxial growth system, a first passivation layer on the AlxGa1-xN barrier layer, wherein the first passivation layer is deposited in-situ in the epitaxial growth system directly after the epitaxial growth of the AlxGa1-xN barrier layer and prior to air exposure, wherein the first passivation layer has a composition AlzGa1-zN, wherein z is in a range of 0 to 1, wherein a thickness of the first passivation layer is between about 1 nm and about 5 nm; depositing, in the epitaxial growth system, an in-situ passivation layer on the first passivation layer, wherein the in-situ passivation layer has a composition AlySi1-yN, and wherein y is in a range of 0 to 1; depositing a second passivation layer on the in-situ passivation layer; forming device isolation regions; forming a drain ohmic contact coupled to the channel layer at a first end of the 2DEG channel; forming a source ohmic contact coupled to the channel layer at a second end of the 2DEG channel opposite the first end of the channel; and forming a T-shaped gate electrode at a location on a surface between the drain ohmic contact and the source ohmic contact, the T-shaped gate electrode recessed through the second passivation layer and in-situ passivation layer and contacting the first passivation layer, wherein the T-shaped gate electrode includes a neck portion that extends a first distance above the surface to a head portion of the T-shaped gate electrode.

Example 25: The method of Example 24, further comprising, prior to depositing a second passivation layer, removing the in-situ passivation layer prior to depositing the second passivation layer.

Example 26: The method of Example 24, further comprising: depositing a third passivation layer to cover the surface between the drain ohmic contact and the source ohmic contact and cover the T-shaped gate electrode.

Example 27: The method of Example 26, further comprising: depositing a source-connected metal field plate on a top surface of the third passivation layer and located between a source edge of the T-shaped gate electrode and an edge of the drain ohmic contact.

Example 28: The method of Example 24, further comprising: forming device isolation regions prior to deposition of a second passivation layer on the in-situ passivation layer.

Example 29: A method of fabricating a gallium nitride (GaN) based high electron mobility transistor (HEMT), the method comprising: providing a substrate; epitaxially growing, in an epitaxial growth system, a back barrier layer including Al and N on the substrate; epitaxially growing, in the epitaxial growth system, a channel layer including Ga and N on the back barrier layer; epitaxially growing, in the epitaxial growth system, an interlayer on the channel layer, wherein the interlayer has a composition AlwGa1-wN, wherein w is in a range of 0.2 and 1, and wherein the interlayer and the channel layer are arranged to form a two-dimensional electron gas (2DEG) channel at an interface of the interlayer and the channel layer; epitaxially growing, in the epitaxial growth system, an AlxGa1-xN barrier layer on the interlayer, wherein x is in a range of 0.2 to 1; epitaxially growing, in the epitaxial growth system, a first passivation layer on the AlxGa1-xN barrier layer, wherein the first passivation layer is deposited in-situ in the epitaxial growth system directly after the epitaxial growth of the AlxGa1-xN barrier layer and prior to air exposure, wherein the first passivation layer has a composition AlzGa1-zN, wherein z is in a range of 0 to 1, wherein a thickness of the first passivation layer is between about 1 nm and about 5 nm; depositing, in the epitaxial growth system, an in-situ passivation layer on the first passivation layer, wherein the in-situ passivation layer has a composition AlySi1-yN, and wherein y is in a range of 0 to 1; forming device isolation regions; forming a drain ohmic contact coupled to the channel layer at a first end of the 2DEG channel; forming a source ohmic contact coupled to the channel layer at a second end of the 2DEG channel opposite the first end of the channel; and forming a T-shaped gate electrode at a location on a surface between the drain ohmic contact and the source ohmic contact, the T-shaped gate electrode contacting the first passivation layer, wherein the T-shaped gate electrode includes a neck portion that extends a first distance above the surface to a head portion of the T-shaped gate electrode; and depositing a second passivation layer that continuously extends from an upper surface of the drain ohmic contact to an upper surface of the source ohmic contact to cover the surface and to cover the T-shaped gate electrode.

Example 30: The method of Example 29, further comprising, prior to depositing a second passivation layer, removing the in-situ passivation layer prior to depositing the second passivation layer.

Example 31: The method of Example 29, further comprising depositing a source-connected metal field plate on a top surface of the second passivation layer and located between a source edge of the T-shaped gate electrode and an edge of the drain ohmic contact.

Numerous benefits are achieved by way of the present disclosure over conventional techniques. For example, embodiments of the present disclosure provide improved current collapse in a high electron mobility transistor (HEMT) using aluminum nitride back barrier and in-situ two-step passivation. Embodiments enable reduction of current collapse in GaN-based HEMTs while improving thermal performance of the GaN-based HEMTs. In some embodiments, the GaN-based HEMT can be fabricated with an aluminum nitride (AlN) back barrier layer, where the GaN-based HEMT can be formed using a two-step, in-situ passivation fabrication process. The AlN back barrier uniquely enables a reduction of buffer layer trap states and improved thermal performance by using a material having wider bandgap than AlGaN alloys while at the same time improving thermal conductivity as compared to GaN and AlGaN alloys. The in-situ deposited passivation layers enable reduction of trap states and improve performance of the GaN-based HEMT by reducing current collapse that may be present in the HEMT. In various embodiments, the in-situ deposited passivation layer can be formed from material such as, but not limited to, SiN, AlN, or an alloy of the two. In some embodiments, the AlN passivation may be amorphous or crystalline. In various embodiments, the AlN barrier can reduce surface traps while improving thermal spreading within the heterostructure device. In some embodiments, an additional passivation layer of LPCVD or PECVD SiN can be added ex situ to thicken the passivation layer and position the surface of the heterostructure device further from the device's active area. In this way, current collapse can be further reduced in the GaN-based HEMT. These and other embodiments of the disclosure, along with many of its advantages and features, are described in more detail in conjunction with the text below and attached figures.

### BRIEF DESCRIPTION OF THE DRAWINGS

Aspects of the present disclosure will now be described more fully hereinafter with reference to the accompanying drawings, which are intended to be read in conjunction with both this summary, the detailed description and any preferred and/or particular embodiments specifically discussed or otherwise disclosed. The various aspects may, however, be embodied in many different forms and should not be construed as limited to the embodiments as set forth herein; rather, these embodiments are provided by way of illustration only and so that this disclosure will be thorough and complete and will fully convey the full scope to those skilled in the art.

FIG. 1 illustrates a cross-sectional view of a heterostructure device having an aluminum nitride (AlN) back barrier layer and fabricated using a two-step, in-situ passivation fabrication process according to embodiments of the disclosure.

FIGS. 2A-2F show cross sectional views illustrating a method of fabricating the heterostructure device illustrated in FIG. 1, according to some embodiments of the disclosure.

FIG. 3 illustrates a simplified flowchart illustrating a method for fabricating the heterostructure device illustrated in FIG. 1, according to an embodiment of the disclosure.

FIGS. 4A-4F are cross section views illustrating an alternate method of fabricating a heterostructure device, according to certain embodiments of the disclosure.

FIG. 5 illustrates a simplified flowchart illustrating a method for fabricating the heterostructure device illustrated in FIG. 4F, according to an embodiment of the disclosure.

FIG. 6 illustrates a cross-sectional view of a heterostructure device fabricated using a multi-step passivation fabrication process according to embodiments of the disclosure.

FIGS. 7A-7G show cross sectional views illustrating a method of fabricating the heterostructure device illustrated in FIG. 6, according to some embodiments of the disclosure.

FIG. 8 illustrates a simplified flowchart illustrating a method for fabricating the heterostructure device illustrated in FIG. 6, according to an embodiment of the disclosure.

FIG. 9 illustrates a cross-sectional view of a heterostructure device fabricated using a multi-step passivation fabrication process according to embodiments of the disclosure.

FIG. 10 illustrates an example variation of the heterostructure device in FIG. 9 according to embodiments of the disclosure.

FIG. 11 illustrates another example variation of the heterostructure device in FIG. 9 according to embodiments of the disclosure.

FIG. 12 illustrates yet another example variation of the heterostructure device in FIG. 9 according to embodiments of the disclosure.

FIG. 13 illustrates a simplified flowchart illustrating a method for fabricating the heterostructure device illustrated in FIG. 9, according to an embodiment of the disclosure.

FIG. 14 illustrates a simplified flowchart illustrating another method for fabricating a heterostructure device, according to an embodiment of the disclosure.

### DETAILED DESCRIPTION OF SPECIFIC EMBODIMENTS

The described embodiments relate generally to GaN-based high electron mobility transistor (HEMT) devices. More particularly, embodiments of the present disclosure provide improved current collapse performance in the GaN-based HEMT by use of an aluminum nitride (AlN) back barrier along with in-situ two-step passivation fabrication method.

GaN HEMTs used in RF amplifiers may have trap states that can degrade performance of the GaN HEMT. Two types of trap states may be present in GaN HEMT devices: surface traps and bulk traps. Surface traps may be located on a top surface of GaN HEMT devices, which is typically the air-exposed top side of the barrier layer. These trap states may be broken bonds on the semiconductor surface or formed due to chemical modification of the surface such as Ga—O bonds, which form as the surface oxidizes. Additional trap state generation and general reduction of surface insulation may be induced by air exposure. In current approaches, a passivation layer may be deposited on the top surface to compensate and reduce the trap states and prevent electron trapping. Commonly used passivation layers can include materials such as silicon nitride (SiN).

In current approaches, the passivation layer may be deposited using fabrication methods such as plasma-enhanced chemical vapor deposition (PECVD) and/or low pressure chemical vapor deposition (LPCVD). In current approaches, the fabrication process may be performed ex-situ, i.e., the GaN HEMT devices may be exposed to air for a period of time between when the epitaxial structure is grown and when the passivation layer is deposited.

In addition to surface traps, bulk trap states may exist near the conduction channel of the GaN HEMT, and in the buffer regions below the conduction channel. These trap states may be introduced by chemical defects such as acceptor atoms that are used as dopants to make the GaN buffer layer insulating.

A relatively thick GaN buffer layer that is undoped may exhibit electrical conductivity due to unintentional donor doping from background oxygen, silicon, or nitrogen vacancies, which can induce loss of the RF signal in the amplifier. To reduce the electrical conductivity of the GaN buffer layer, deep level acceptor dopants, such as Carbon, Iron, or Manganese, may be introduced to make the GaN buffer layer semi-insulating. However, these acceptor donors can introduce trap states in the GaN buffer. These GaN buffer trap states may cause hot electrons from the channel region to leak into the buffer below the channel and become trapped. Therefore, current approaches have an inherent tradeoff between buffer conductivity and buffer trap states.

Embodiments of the present disclosure can break this tradeoff, minimizing electrical conductivity and trap states in the buffer layer, and therefore reduce current collapse in GaN HEMTs while also improving thermal performance of the GaN HEMTs. In some embodiments, a heterostructure device structure can be fabricated with an aluminum nitride (AlN) back barrier layer. The AlN back barrier may also be referred to as the AlN buffer. The heterostructure device structure can be formed using a two-step, in-situ passivation fabrication process. The AlN back barrier/buffer uniquely enables a reduction of buffer layer trap states and improved thermal performance by using a material having wider bandgap than AlGaN alloys while at the same time improving thermal conductivity as compared to GaN and AlGaN alloys. In various embodiments, the in-situ deposited passivation layer(s) can be formed from material such as, but not limited to, SiN, AlN, or an alloy of the two. In some embodiments, AlN passivation may be amorphous or crystalline. In various embodiments, the AlN barrier can reduce surface traps while improving thermal spreading within the heterostructure device. In some embodiments, an additional passivation layer of LPCVD or PECVD SiN can be added ex situ to thicken the passivation layer and position the surface of the heterostructure device further from the device's active area.

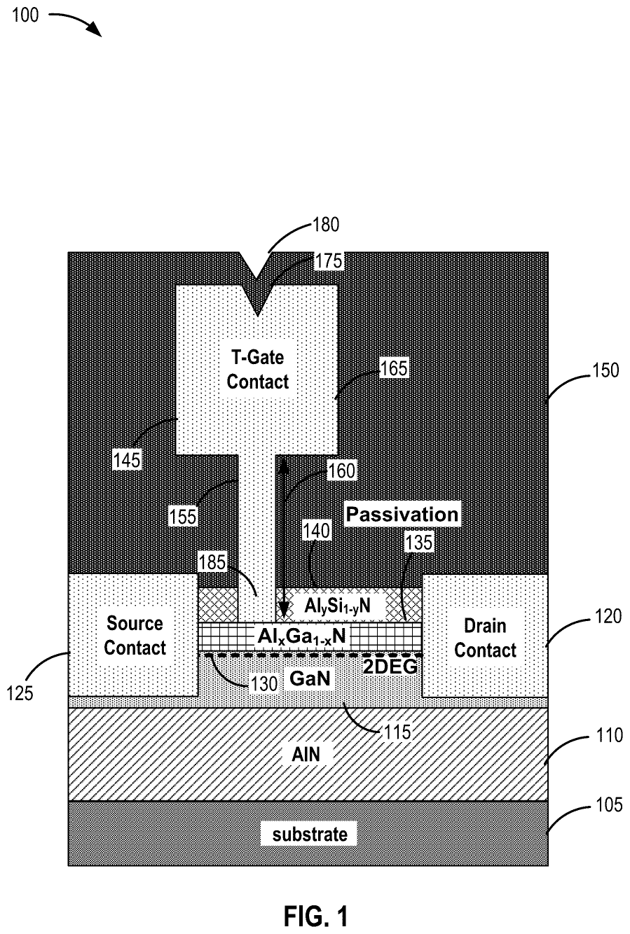

FIG. 1 illustrates a cross-sectional view of heterostructure device having an AlN back barrier layer and fabricated using a two-step, in-situ passivation fabrication process according to embodiments of the disclosure. As shown in FIG. 1, a heterostructure device 100 can include an AlN back barrier layer 110 formed on a substrate 105, such as, but not limited to, SiC, Al₂O₃, Silicon, AlN, or the like. In some embodiments, the AlN back barrier layer 110 can be formed to a thickness in a range of, for example, 100 nm to 700 nm. In various embodiments, the AlN back barrier layer 110 can be formed to a thickness in a range of 200 nm to 500 nm, while in other embodiments the AlN back barrier layer 110 can be formed to a thickness in a range of 300 nm to 400 nm. As appreciated by one of ordinary skill in the art having the benefit of this disclosure, the thickness of the AlN back barrier layer 110 can be set to any suitable value. The AlN back barrier layer 110 can be formed using any type of process that provides for epitaxial formation of the AlN layer, such as MBE, MOCVD, or the like.

The heterostructure device 100 can include a GaN channel layer 115 formed on the AlN back barrier layer 110. The GaN channel layer 115 can be epitaxially grown on the AlN back barrier layer 110 so that the lattice of the GaN channel layer 115 can be matched to the lattice of the AlN back barrier layer 110. This can result in a compressively strained GaN channel layer 115. In some embodiments, the GaN channel layer 115 can be formed to a thickness in a range of, for example, 100 nm to 700 nm. In various embodiments, the GaN channel layer 115 can be formed to a thickness in a range of 200 nm to 500 nm, while in other embodiments the GaN channel layer 115 can be formed to a thickness in a range of 300 nm to 400 nm. As appreciated by one of ordinary skill in the art having the benefit of this disclosure, the thickness of the GaN channel layer 115 can be set to any suitable value. The GaN channel layer 115 can be formed to include other materials, such as In or Al. The composition of the In or Al in the GaN channel layer can be graded or uniform throughout the thickness.

The heterostructure device 100 can further include an AlₓGa₁₋ₓN layer 135 formed on the GaN channel layer 115. In some embodiments, the AlₓGa₁₋ₓN layer 135 can be formed to a thickness in a range of, for example, 1 nm to 70 nm. In various embodiments, the AlₓGa₁₋ₓN layer 135 can be formed to a thickness in a range of 2 nm to 50 nm, while in other embodiments the AlₓGa₁₋ₓN layer 135 can be formed to a thickness in a range of 3 nm to 30 nm. As appreciated by one of ordinary skill in the art having the benefit of this disclosure, the thickness of the AlₓGa₁₋ₓN layer 135 can be set to any suitable value. In some embodiments, a value for x can be in a range of, for example, 0.1 to 1. In various embodiments, the value for x can be in a range of 0.15 to 1, while in other embodiments the value for x can be in a range of 0.2 to 1.

The AlₓGa₁₋ₓN layer 135 can be formed on the GaN channel layer 115 to provide a heterojunction for the HEMT device where a channel region 130 is formed in the GaN channel layer 115 near the AlₓGa₁₋ₓN/GaN interface. It will be understood that the channel region 130 can be a two-dimensional electron gas (2DEG) channel region. In some embodiments, the AlₓGa₁₋ₓN layer 135 may be epitaxially grown on the GaN channel layer 115.

The heterostructure device 100 can further include a source ohmic contact 125 and a drain ohmic contact 120. The source ohmic contact 125 may be recessed into the GaN channel layer 115 at a first end of the 2DEG channel region 130 and the drain ohmic contact 120 may be recessed into the GaN channel layer 115 at a second end of the 2DEG channel region 130 opposite the first end of the GaN channel layer 115. In some embodiments, the ohmic contacts may include a metal or a combination of metals, such as Ti and/or Au, or other metals may also be used. The ohmic contact metal stack may be deposited on the AlₓGa₁₋ₓN layer 135 and annealed at temperatures in the range of 400 to 1200° C., such that the metal stack fuses through the AlₓGa₁₋ₓN layer 135 to make contact with the 2DEG channel region. In some embodiments, the ohmic contacts may be formed by first forming a recessed region by dry etching followed by n-type doped gallium nitride grown epitaxially via MBE, MOCVD, or the like, to make contact to the 2DEG channel region. The source and drain ohmic contacts can be coupled to the AlₓGa₁₋ₓN layer 135 and the GaN channel layer 115.

The heterostructure device 100 can further include T-shaped gate electrode 145. The T-shaped gate electrode 145 may be formed to include a neck portion 155 that contacts the AlₓGa₁₋ₓN layer 135 and extends away from the channel region 130. At the first distance 160 from the AlₓGa₁₋ₓN layer, the T-shaped gate electrode 145 transitions to a head portion 165 that has a second width that is wider than the width of the neck portion 155. In some embodiments, the T-shaped gate electrode 145 includes a gate electrode recess 175 in an uppermost surface of the head portion of the T-shaped gate electrode 145. In some embodiments, the gate electrode may be T-shaped. In various embodiments, the heterostructure device 100 includes a passivation layer recess 180 in an upper surface of the second passivation layer 150 above the gate electrode recess 175, where the second passivation layer recess 180 has a shape that conforms to a shape of the gate electrode recess 175. In some embodiments, the T-shaped gate electrode 145 may include metal or a combination of metals, such as Ni and/or Au. Other metals may also be used.

In some embodiments, the gate electrode recess 175 may be disposed on an upper surface of the second passivation layer 150.

In some embodiments, a first passivation layer 140 and a second passivation layer 150 can be formed over the ohmic contacts 125 and 120, the T-shaped gate electrode 145 (including the head portion 165) and the AlₓGa₁₋ₓN layer 135. The first and second passivation layers can be formed by a two-step passivation process where the first passivation layer 140 having a composition Al_{y}Si_{1-y}N (y in the range of 0 to 1) may be deposited in the same epitaxial growth system directly after a growth of the AlₓGa₁₋ₓN/GaN/AlN heterostructure prior to air exposure, followed by formation of the second passivation layer 150 by an LPCVD/PECVD deposition of SiN before device processing. In some embodiments, the SiN deposition may take place after the device processing. The heterostructure device 100 can further include a recessed region 185 through the AlSiN layer. The recessed region 185 can be used to form gate contact to the AlₓGa₁₋ₓN layer 135 enabling improved gate length to back barrier thickness ratio. In various embodiments, a first passivation layer 140 and a second passivation layer 150 can be formed over the ohmic contacts 125 and 120 and the AlₓGa₁₋ₓN layer 135, while the head portion 165 of the T-shaped gate electrode 145 can be formed over an upper surface of the second passivation layer 150.

In some embodiments, the T-shaped gate electrode 145 may be formed by recessing through the in-situ formed first passivation layer having a composition AlSiN layer to form the gate contact to the AlₓGa₁₋ₓN barrier. In this way, the heterostructure device 100 can have an improved gate length to barrier thickness ratio. In various embodiments, an additional passivation layer of LPCVD or PECVD SiN can be added ex situ to thicken the passivation and move the surface region of the heterostructure device 100 further from the device's active area.

In some embodiments, the first passivation layer 140 having a composition Al_{y}Si_{1-y}N can be formed to a thickness in a range of, for example, 1 nm to 100 nm. In various embodiments, the first passivation layer 140 having a composition Al_{y}Si_{1-y}N can be formed to a thickness in a range of 2 nm to 75 nm, while in other embodiments the first passivation layer 140 can be formed to a thickness in a range of 5 nm to 50 nm. As appreciated by one of ordinary skill in the art having the benefit of this disclosure, the thickness of the first passivation layer 140 can be set to any suitable value.

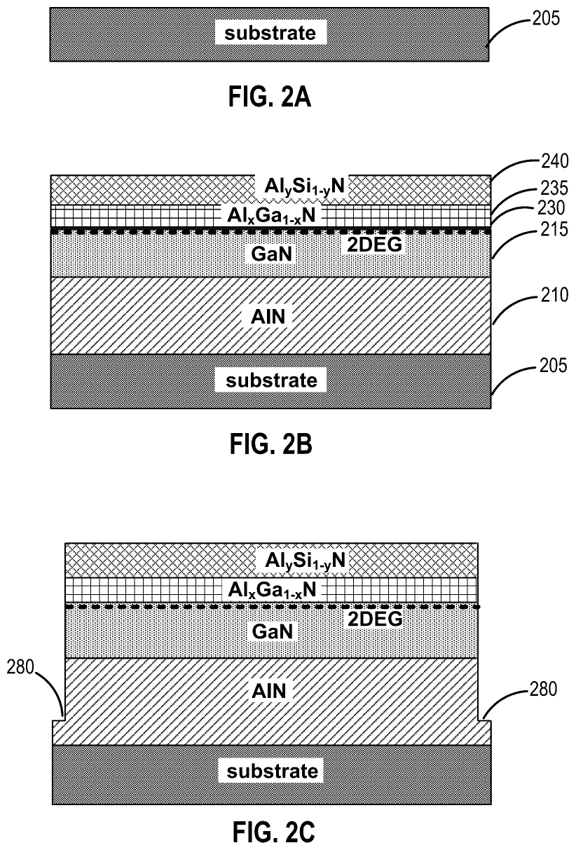

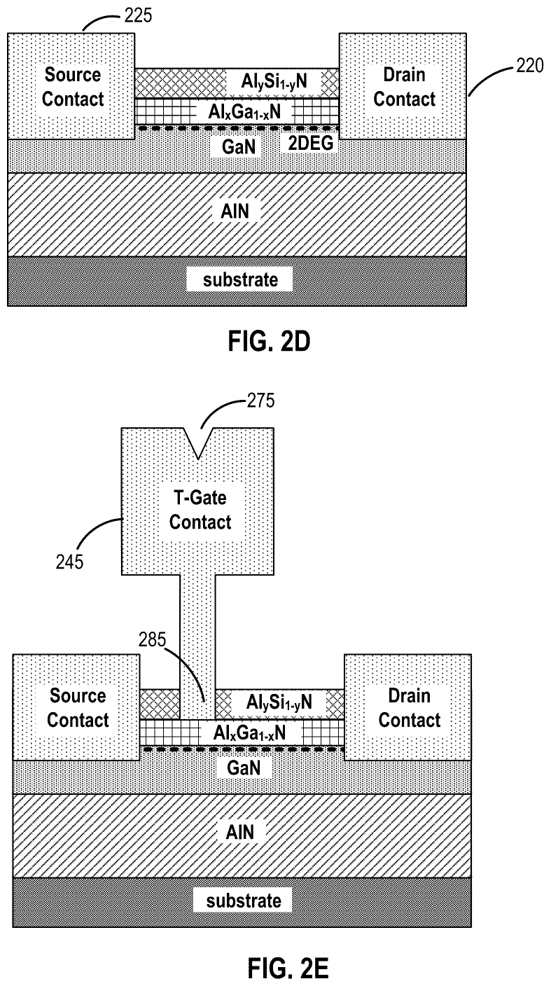

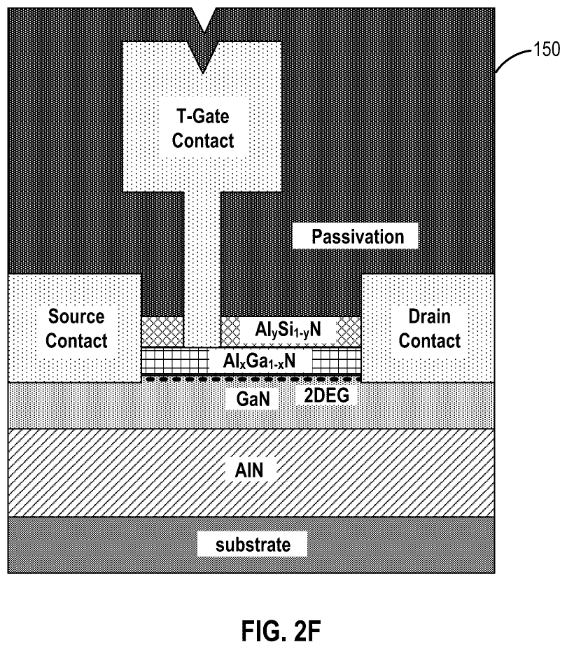

FIGS. 2A-2F show cross sectional views illustrating a method of fabricating the heterostructure device 100, according to some embodiment of the disclosure. The illustrated method may also be referred to as passivation last process (via plasma-enhanced chemical vapor deposition). As shown in FIG. 2A, a substrate 205 is provided. FIG. 2B shows the epitaxially grown epi layers over the substrate 205. The epitaxially grown epi layers may include an AlN layer 210, a GaN layer 215, and an AlₓGa₁₋ₓN layer 235. FIG. 2B further illustrates a first passivation layer Al_{y}Si_{1-y}N 240 deposited on the AlₓGa₁₋ₓN layer 235. A 2DEG layer 230 may be formed at the interface of the AlₓGa₁₋ₓN/GaN layers. FIG. 2C shows the structure after formation of device isolation regions 280. FIG. 2D shows the structure after the formation of ohmic contacts 220 and 225. In some embodiments, the ohmic contacts may be formed by depositing metals on a surface of the AlₓGa₁₋ₓN layer 235 followed by annealing at relatively high temperatures such that the metals fuse through the AlₓGa₁₋ₓN layer 235 to form contact with the 2DEG channel region. In various embodiments, the ohmic contacts may be formed by forming a recessed region by dry etching followed by regrowing n-type doped GaN to form contacts to the 2DEG channel region. FIG. 2E shows a recessed region 285 definition through first passivation layer Al_{y}Si_{1-y}N 240 and deposition of the T-shaped gate. The T-shaped gate electrode may be disposed at a location on the surface between the drain ohmic contact and the source ohmic contact, where the T-shaped gate electrode can include a neck portion that extends a first distance 160 above the surface to a head portion 165 of the T-shaped gate electrode. FIG. 2F shows formation of the second passivation layer 150. The second passivation layer may be formed by a PECVD process. The second passivation layer 150 may be disposed on the first passivation layer and can continuously extend from an upper surface of the drain ohmic contact to an upper surface of the source ohmic contact to cover the surface and to cover the T-shaped gate electrode 245 including into the gate electrode recess 275. The second passivation layer 150 can further include a passivation layer recess in an upper surface of the second passivation layer 150 above the gate electrode recess 275, where the passivation layer recess may have a passivation layer recess shape that conforms to the shape of the gate electrode recess 275.

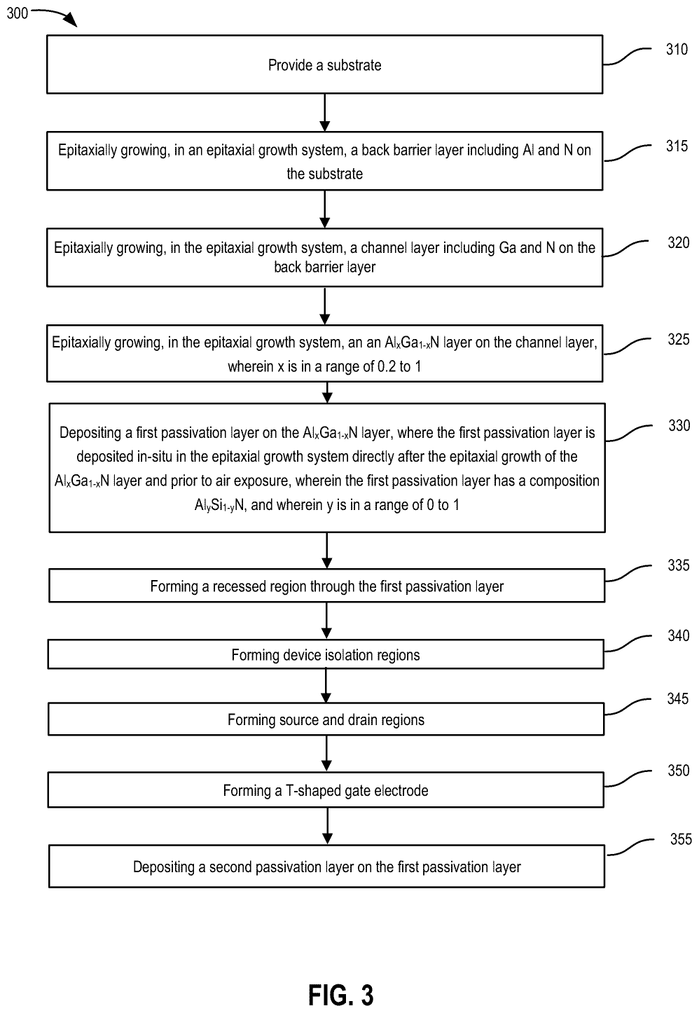

FIG. 3 illustrates a simplified flowchart illustrating a method 300 for fabricating a heterostructure device 100 according to an embodiment of the disclosure. As illustrated in FIG. 3, the method of fabricating the heterostructure device 100 includes providing a substrate (310).

The method also includes epitaxially growing, in an epitaxial growth system, a back barrier layer including Al and N on the substrate (315). The method also includes epitaxially growing, in the epitaxial growth system, a channel layer including Ga and N on the back barrier layer (320).

Additionally, the method includes epitaxially growing, in the epitaxial growth system, an AlₓGa₁₋ₓN layer on the channel layer, where x is in a range of 0.2 to 1, and where the AlₓGa₁₋ₓN layer and the channel layer are arranged to form a two-dimensional electron gas (2DEG) channel at an interface of the AlₓGa₁₋ₓN layer and the channel layer (325). The method further includes depositing a first passivation layer on the AlₓGa₁₋ₓN layer, where the first passivation layer is deposited in-situ in the epitaxial growth system directly after the epitaxial growth of the AlₓGa₁₋ₓN layer and prior to air exposure, where the first passivation layer has a composition Al_{y}Si_{1-y}N, where y is in a range of 0 to 1 (330). The method also includes forming a recessed region through the first passivation layer (335). The method further includes forming device isolation regions (340).

The method also includes forming source and drain regions, which includes forming a drain ohmic contact recessed into the channel layer at a first end of the 2DEG channel and forming a source ohmic contact recessed into the channel layer at a second end of the 2DEG channel opposite the first end of the channel (345). In some embodiments, the ohmic contacts may be formed by depositing metals on a surface of the AlₓGa₁₋ₓN layer 235 followed by annealing at relatively high temperatures such that the metals fuse through the AlₓGa₁₋ₓN layer 235 to form contact with the 2DEG channel region. In various embodiments, the ohmic contacts may be formed by forming a recessed region by dry etching followed by regrowing n-type doped GaN to form contacts to the 2DEG channel region. In some examples, step 345 (forming the source and drain regions) is performed prior to step 340 (forming device isolation regions). The method also includes forming a T-shaped gate electrode at a location on a surface between the drain ohmic contact and the source ohmic contact, the T-shaped gate electrode contacting the AlₓGa₁₋ₓN layer through the recessed region, wherein the T-shaped gate electrode includes a neck portion that extends a first distance above the surface to a head portion of the T-shaped gate electrode (350). The method also includes depositing a second passivation layer on the first passivation layer (355).

It should be appreciated that the specific steps illustrated in FIG. 3 provide a particular method of fabricating a heterostructure device according to an embodiment of the disclosure. Other sequences of steps may also be performed according to alternative embodiments. For example, alternative embodiments of the disclosure may perform the steps outlined above in a different order. Moreover, the individual steps illustrated in FIG. 3 may include multiple sub-steps that may be performed in various sequences as appropriate to the individual step. Furthermore, additional steps may be added or removed depending on the particular applications. One of ordinary skill in the art would recognize many variations, modifications, and alternatives.

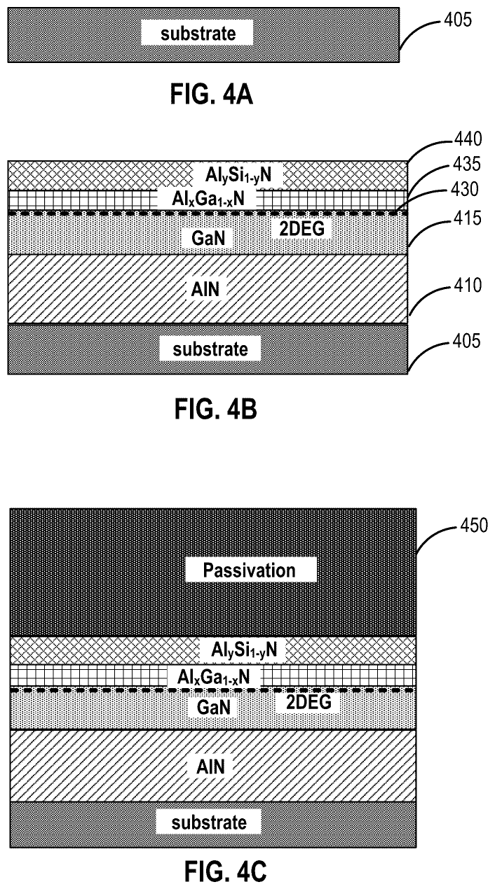

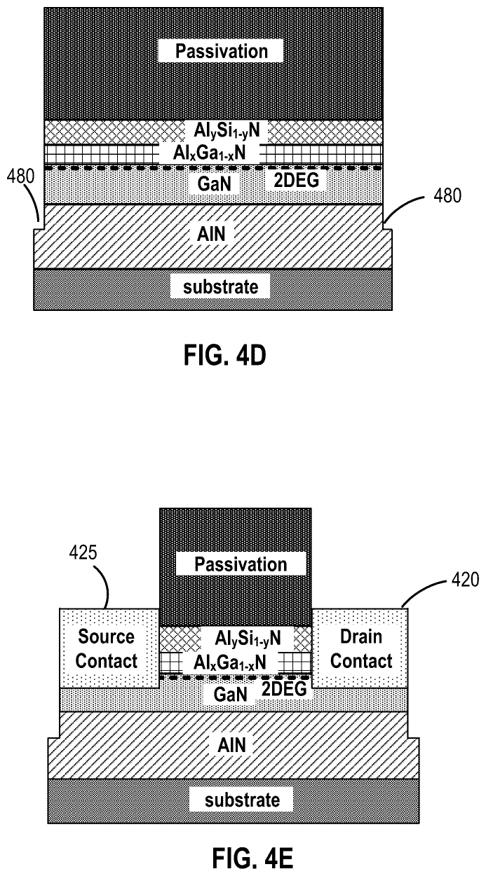

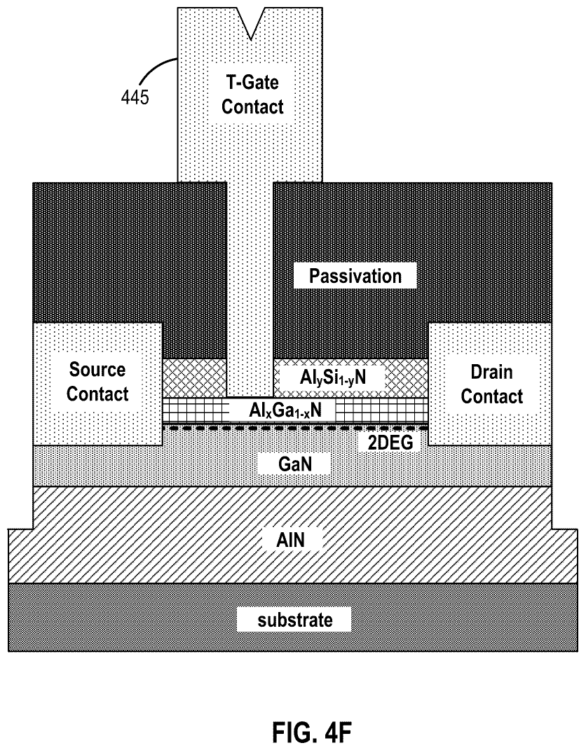

FIGS. 4A-4F are cross section views illustrating an alternate method of fabricating the heterostructure device 100, according to certain embodiment of the disclosure. This method of fabrication may also be referred to as a passivation first process (via low pressure chemical vapor deposition). As shown in FIG. 4A, a substrate 405 is provided. FIG. 4B shows the substrate 405 after completion of epitaxially grown epi layers. The epitaxially grown epi layers may include an AlN layer 410, a GaN layer 415, an AlₓGa₁₋ₓN layer 435. A first passivation layer Al_{y}Si_{1-y}N 440 can be deposited over the AlₓGa₁₋ₓN layer 435. A 2DEG layer 430 may be formed at the interface of the AlₓGa₁₋ₓN/GaN layers. FIG. 4C shows the structure after formation of the second passivation layer 450 over the first passivation layer Al_{y}Si_{1-y}N 440 by methods such as, but not limited to, LPCVD. FIG. 4D shows the structure after formation of isolation regions 480 by methods such as, but not limited to, dry etch or ion implantation. FIG. 4E shows the structure after the formation of ohmic contacts 420 and 425. In some embodiments, the ohmic contacts may be formed by depositing metals on a surface of the AlₓGa₁₋ₓN layer 435 followed by annealing at relatively high temperatures such that the metals fuse through the AlₓGa₁₋ₓN layer 435 to form contact with the 2DEG channel region. In various embodiments, the ohmic contacts may be formed by forming a recessed region by dry etching followed by regrowing n-type doped GaN to form contacts to the 2DEG channel region. FIG. 4F shows the structure after formation of a recess into the first and second passivation layers, and further shows the structure after the deposition of the gate 445 electrode. As shown in FIG. 4F, the head portion of the T-gate electrode is disposed above an upper surface of the second passivation layer 450.

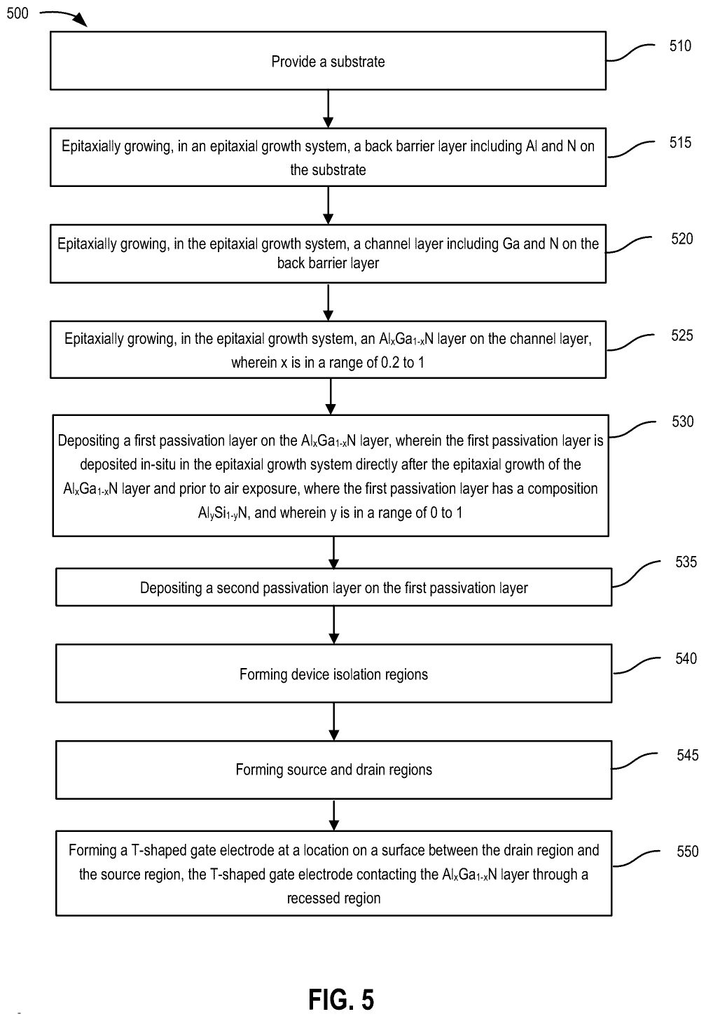

FIG. 5 illustrates a simplified flowchart illustrating a method 500 for fabricating a heterostructure device 100 according to an embodiment of the disclosure. As illustrated in FIG. 5, the method of fabricating the heterostructure device 100 includes providing a substrate (510).

The method also includes epitaxially growing, in an epitaxial growth system, a back barrier layer including Al and N on the substrate (515). The method further includes epitaxially growing, in the epitaxial growth system, a channel layer including Ga and N on the back barrier layer (520).

Additionally, the method includes epitaxially growing, in the epitaxial growth system, an AlₓGa₁₋ₓN layer on the channel layer, wherein x is in a range of 0.2 to 1, and wherein the AlₓGa₁₋ₓN layer (525). The method also includes depositing a first passivation layer on the AlₓGa₁₋ₓN layer, where the first passivation layer is deposited in-situ in the epitaxial growth system directly after the epitaxial growth of the AlₓGa₁₋ₓN layer and prior to air exposure, where the first passivation layer has a composition Al_{y}Si_{1-y}N, where y is in a range of 0 to 1 (530).

The method also includes depositing a second passivation layer on the first passivation layer (535). The method further includes forming device isolation regions (540). The method additionally includes forming source and drain regions, which includes forming a drain ohmic contact recessed into the channel layer at a first end of the 2DEG channel and forming a source ohmic contact recessed into the channel layer at a second end of the 2DEG channel opposite the first end of the channel (545). In some embodiments, the ohmic contacts may be formed by depositing metals on a surface of the AlₓGa₁₋ₓN layer 435 followed by annealing at relatively high temperatures such that the metals fuse through the AlₓGa₁₋ₓN layer 435 to form contact with the 2DEG channel region. In various embodiments, the ohmic contacts may be formed by forming a recessed region by dry etching followed by regrowing n-type doped GaN to form contacts to the 2DEG channel region. In some examples, the source and drain regions (source and drain ohmic contacts) are formed prior to the device isolation regions. The method also includes forming a T-shaped gate electrode at a location on a surface between the drain ohmic contact and the source ohmic contact, the T-shaped gate electrode contacting the AlₓGa₁₋ₓN layer through a recessed region, where the T-shaped gate electrode includes a neck portion that extends a first distance above the surface to a head portion of the T-shaped gate electrode (550).

It should be appreciated that the specific steps illustrated in FIG. 5 provide a particular method of fabricating a heterostructure device according to an embodiment of the disclosure. Other sequences of steps may also be performed according to alternative embodiments. For example, alternative embodiments of the disclosure may perform the steps outlined above in a different order. Moreover, the individual steps illustrated in FIG. 5 may include multiple sub-steps that may be performed in various sequences as appropriate to the individual step.

Furthermore, additional steps may be added or removed depending on the particular applications.

One of ordinary skill in the art would recognize many variations, modifications, and alternatives.

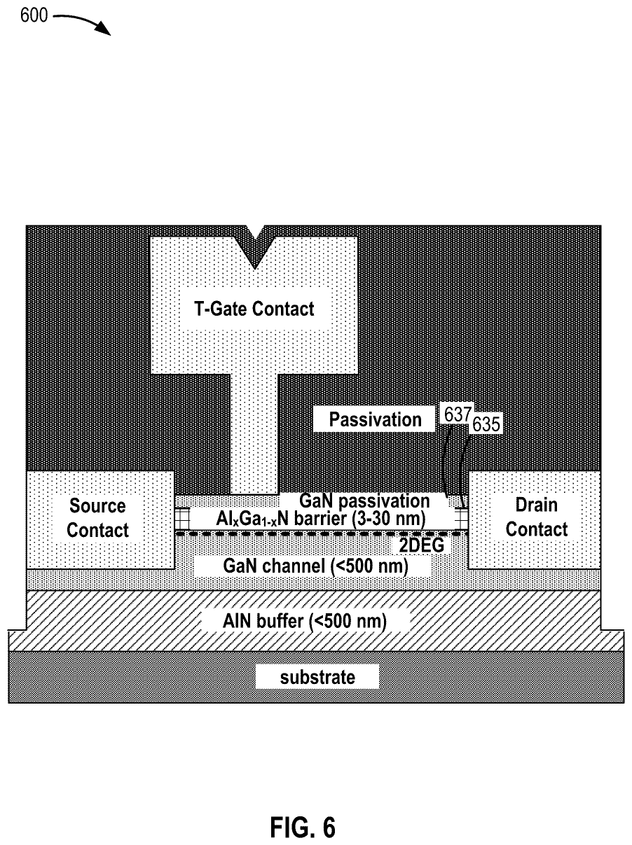

FIG. 6 illustrates a cross-sectional view of a heterostructure device fabricated using a multi-step passivation fabrication process according to embodiments of the disclosure. The description provided in relation to the heterostructure device illustrated in FIG. 1 is applicable to the heterostructure device illustrated in FIG. 6 as appropriate.

In some embodiments, a first passivation layer 637, for example, a GaN layer, can be grown on top of the AlₓGa₁₋ₓN barrier layer 635 during the epitaxial growth process. The GaN layer can provide additional passivating effects that improve yield at the foundry level, especially if the first passivation layer 140 illustrated in FIG. 1 with a composition of Al_{y}Si_{1-y}N is not included or is removed. The first passivation layer 637 can have a thickness, for example, between 1 nm and 5 nm, although thicker GaN layers are included within the scope of the present invention. Alternatively, the first passivation layer 637 can have a different composition, for example, Al_{z}Ga_{1-z}N.

While extremely reliable for passivation, the thin GaN surface can still oxidize when exposed to air, which can be non-ideal since it is in close proximity to the electron channel. Therefore, an amorphous Al_{y}Si_{1-y}N layer (not shown) can be grown as an additional, temporary passivation layer on top of the first passivation layer 637 to protect the first passivation layer 637. The amorphous Al_{y}Si_{1-y}N layer (not shown) would then be removed, either prior to, e.g., right before, processing the wafer or at some point during the processing of the wafer. This can preserve the surface of the first passivation layer 637 by reducing or minimizing the amount of time that the first passivation layer 637 is exposed to air. Thus, the amorphous Al_{y}Si_{1-y}N layer, when used as a temporary layer, can be especially important as several weeks or months may pass between when the wafer is grown and when the wafer is processed.

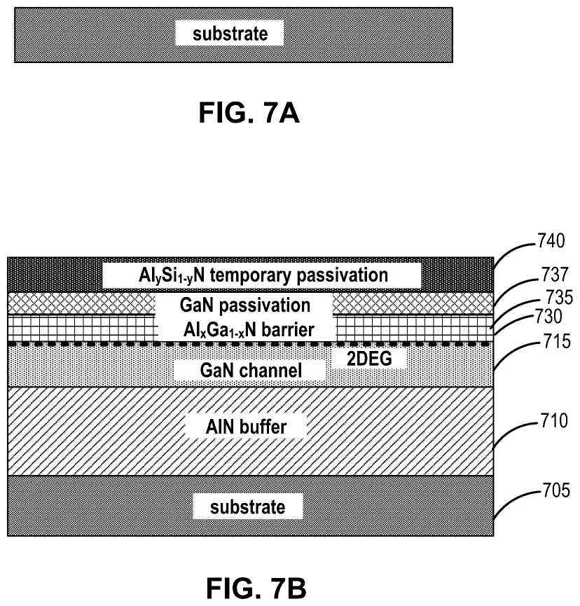

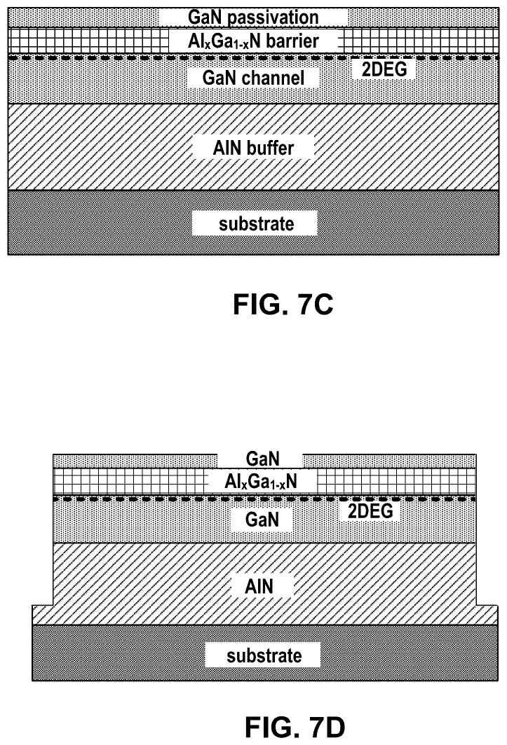

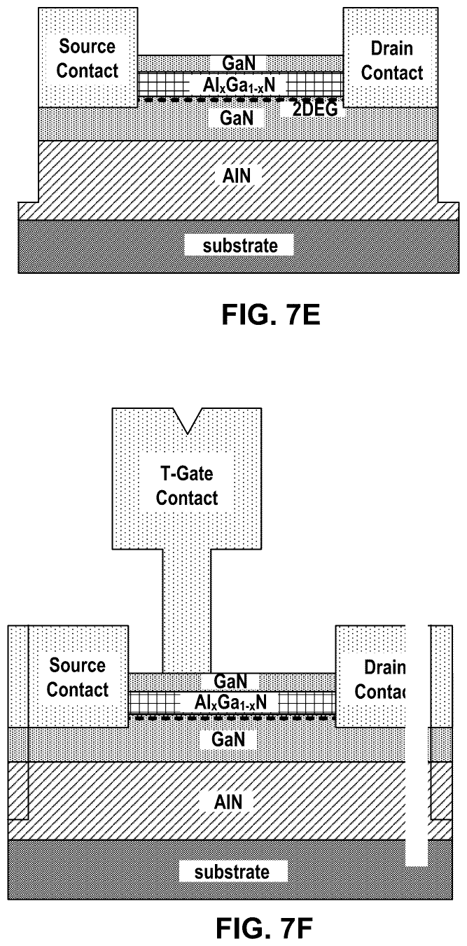

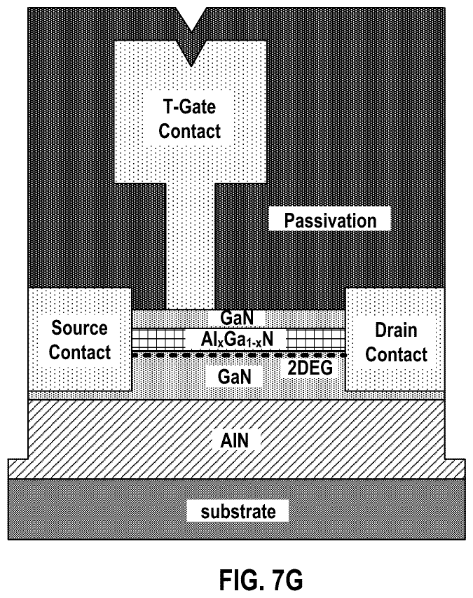

FIGS. 7A-7G show cross sectional views illustrating a method of fabricating the heterostructure device illustrated in FIG. 6, according to some embodiments of the disclosure. The description provided in relation to the method illustrated in FIGS. 2A-2F is applicable to the method illustrated in FIGS. 7A-7G as appropriate.

As illustrated in FIG. 7A, a substrate 705 is provided. FIG. 7B shows the epitaxially grown epi layers over the substrate 705. The epitaxially grown epi layers may include an AlN buffer layer 710, a GaN channel layer 715, and an AlₓGa₁₋ₓN barrier layer 735. A 2DEG layer 730 may be formed at the interface of the GaN channel layer 715 and the AlₓGa₁₋ₓN barrier layer 735. To fabricate the device illustrated in FIG. 6, a first passivation layer 737 (i.e., a first passivation layer 637 in FIG. 6) is grown on top of the AlₓGa₁₋ₓN barrier layer 735 and a temporary Al_{y}Si_{1-y}N layer 740 is grown on top of the first passivation layer 737, as shown in FIG. 7B. The first passivation layer 737 can be an Al_{z}Ga_{1-z}N layer. In the case in which z=0, the first passivation layer 737 is a GaN layer.

The temporary Al_{y}Si_{1-y}N layer 740 can protect the first passivation layer 737 from air exposure and prevent oxidation. FIG. 7C shows that the temporary Al_{y}Si_{1-y}N layer 740 is being removed before the start of fabrication process. The temporary Al_{y}Si_{1-y}N layer 740 can be removed by wet etching (e.g., via buffered oxide etch process). After removal of temporary Al_{y}Si_{1-y}N layer 740 as shown in FIG. 7C, the processes illustrated in FIGS. 7D-7G are similar to the processes illustrated in FIGS. 2C-2F.

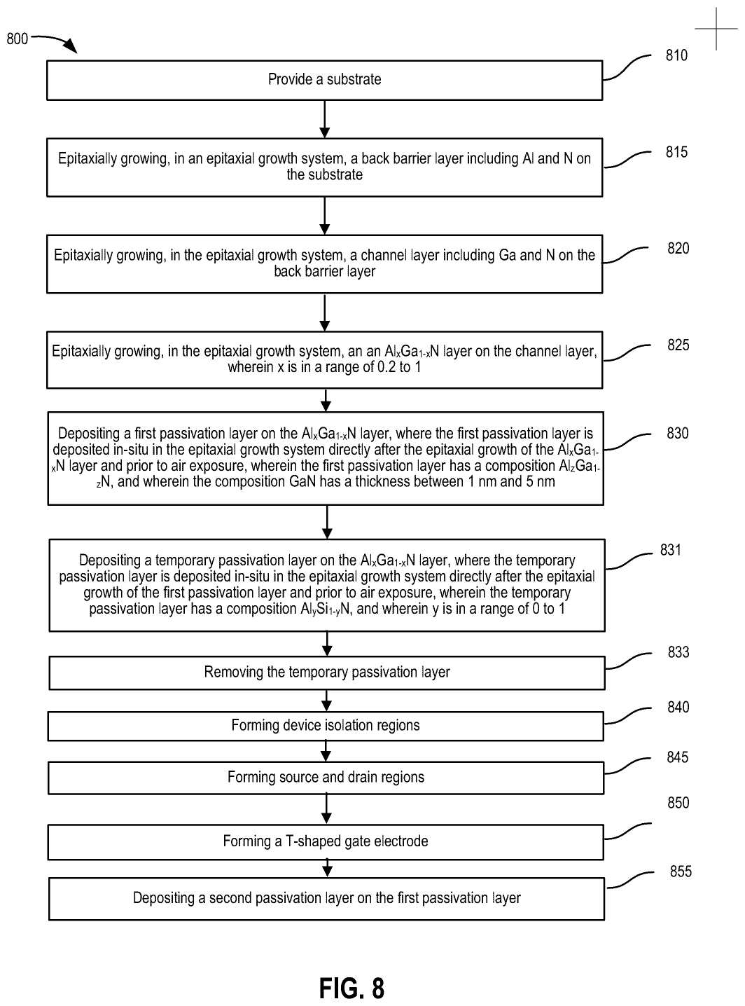

FIG. 8 illustrates a simplified flowchart 800 illustrating a method for fabricating the heterostructure device illustrated in FIG. 6, according to an embodiment of the disclosure. The description provided in relation to the method illustrated in FIG. 3 is applicable to the method illustrated in FIG. 8 as appropriate, both of which are a passivation-last process. Steps 810-825 are similar to steps 310-325. Similar to step 330, at step 830, the method includes depositing a first passivation layer on the AlₓGa₁₋ₓN barrier layer, where the first passivation layer is deposited in-situ in the epitaxial growth system directly after the epitaxial growth of the AlₓGa₁₋ₓN barrier layer and prior to air exposure, wherein the first passivation layer comprises Al_{z}Ga_{1-z}N, wherein z is in a range of 0 to 1, and wherein the first passivation layer has a thickness between 1 nm and 5 nm in some embodiments. However, at step 831, the method includes depositing a temporary passivation layer on the AlₓGa₁₋ₓN barrier layer, where the temporary passivation layer is deposited in-situ in the epitaxial growth system directly after the epitaxial growth of the initial passivation layer and prior to air exposure, wherein the temporary passivation layer has a composition Al_{y}Si_{1-y}N, and wherein y is in a range of 0 to 1. At step 833, the method includes removing the temporary passivation layer. Steps 840-855 are similar to steps 340-355. The method can also include a step of forming a recessed region through the first passivation layer (similar to step 335) after removing the temporary passivation layer (step 833).

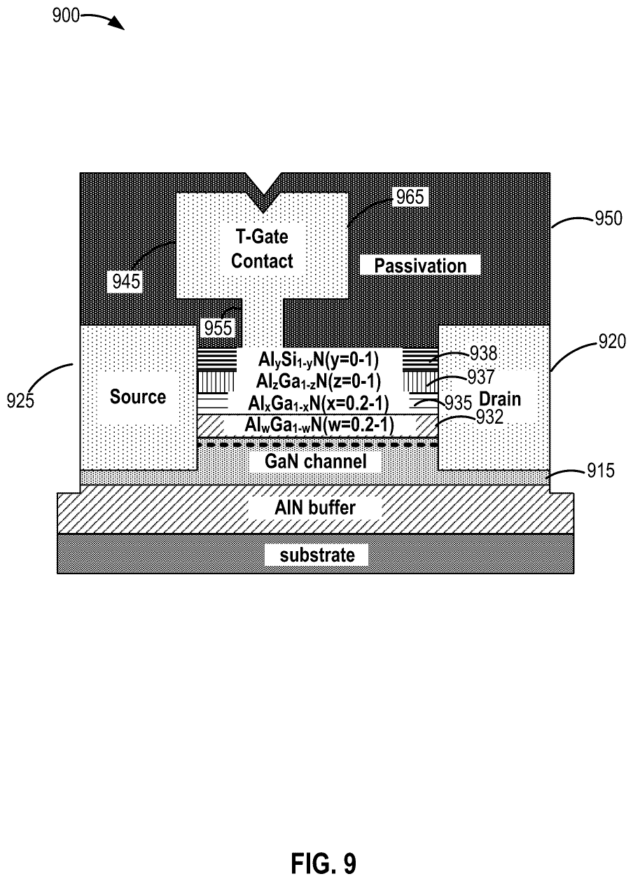

FIG. 9 illustrates a cross-sectional view of a heterostructure device 900 fabricated using a multi-step passivation fabrication process according to embodiments of the disclosure. The description provided in relation to the heterostructure device illustrated in FIG. 1 and FIG. 6 is applicable to the heterostructure device illustrated in FIG. 9 as appropriate. In some embodiments, an interlayer 932 with a composition Al_{w}Ga_{1-w}N where w is in the range between about 0.2 and 1, can be grown on the channel layer 915. An AlₓGa₁₋ₓN barrier layer 935, where x is in the range between about 0.2 and 1, is grown on the interlayer 932. A first passivation layer 937 with a composition Al_{z}Ga_{1-z}N can be grown on the AlₓGa₁₋ₓN barrier layer 935. When fabricating the device in FIG. 6, an amorphous layer with a composition Al_{y}Si_{1-y}N can be deposited and then removed either prior to (e.g., right before) processing the wafer or at some point during the processing of the wafer. In contrast, in FIG. 9, the heterostructure device 900 can include an in-situ passivation layer 938 with a composition Al_{y}Si_{1-y}N on top of the first passivation layer 937. In some examples, a recessed region is formed through the in-situ passivation layer 938 to form a gate contact to the first passivation layer 937. A T-shaped gate electrode 945 is formed at a location on a surface between the drain ohmic contact 920 and the source ohmic contact 925. A second passivation layer 950 is formed on the in-situ passivation layer 938 and continuously extending from an upper surface of the drain ohmic contact 920 to an upper surface of the source ohmic contact 925 to cover the surface between the drain ohmic contact 920 and the source ohmic contact 925, and to cover a bottom surface of the head portion 965 and the neck portion 955 of the T-shaped gate electrode 945. In some examples, the heterostructure device 900 is fabricated in a passivation first process, where the second passivation layer does not cover the top of the T-shaped gate electrode 945. A third passivation layer (not shown) can be formed on the second passivation layer 950 and continuously extending from the upper surface of the drain ohmic contact 920 to the upper surface of the source ohmic contact 925 to cover the surface between the drain ohmic contact 920 and the source ohmic contact 925, and to cover the T-shaped gate electrode 945. In some examples, a source-connected metal field plate (not shown) is deposited on a top surface of the third passivation layer and located between a source edge of the T-shaped gate electrode 945 and an edge of the drain ohmic contact 920.

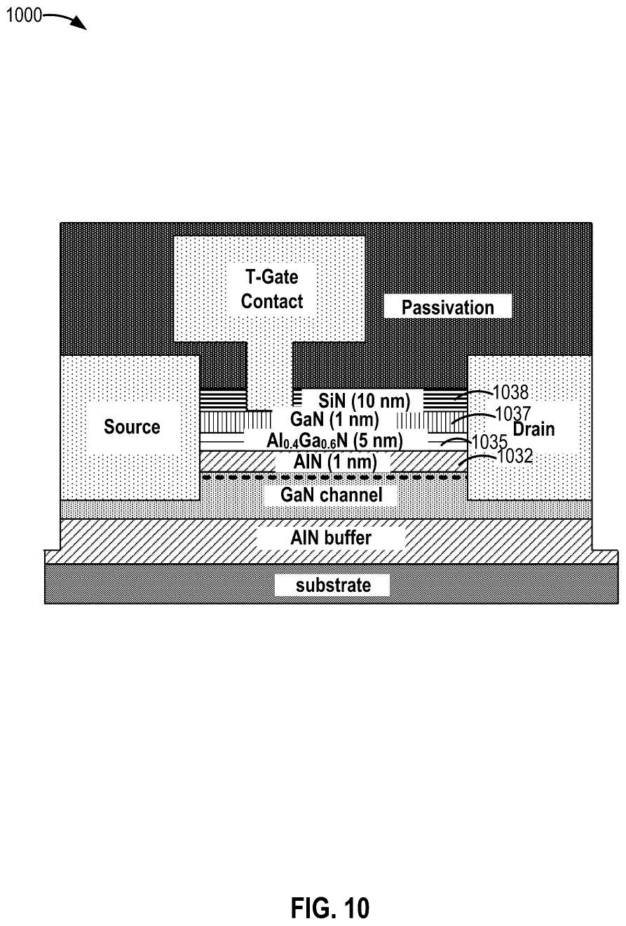

FIG. 10 illustrates an example variation 1000 of the heterostructure device in FIG. 9 according to embodiments of the disclosure. Corresponding to the interlayer 932 with a composition Al_{w}Ga_{1-w}N in FIG. 9, interlayer 1032 is an AlN layer where w=1. Corresponding to the AlₓGa₁₋ₓN barrier layer 935, barrier layer 1035 has a composition Al_{0.4}Ga_{0.6}N where x=0.4.

Corresponding to the first passivation layer 937 with a composition Al_{z}Ga_{1-z}N, the first passivation layer 1037 is a GaN layer where z=0. Corresponding to the in-situ passivation layer 938 with a composition Al_{y}Si_{1-y}N, the in-situ passivation layer 1038 is a SiN layer where y=0.

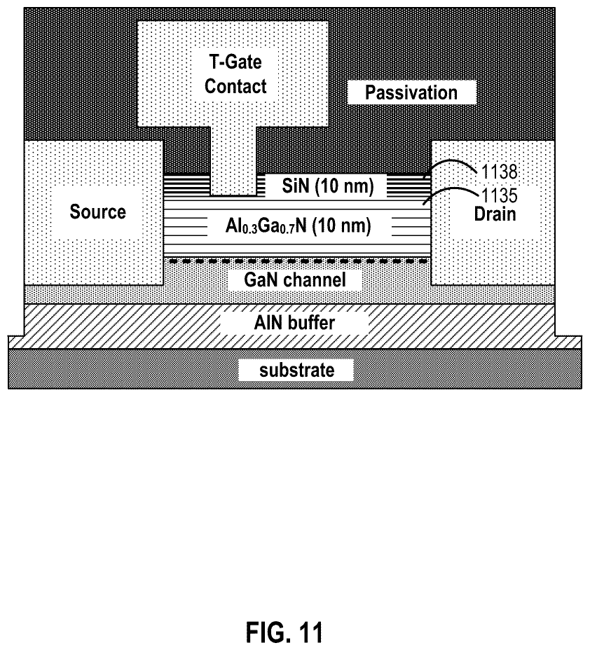

FIG. 11 illustrates another example variation of the heterostructure device in FIG. 9 according to embodiments of the disclosure. Device 1100 in FIG. 11 is similar to the heterostructure device 100 in FIG. 1. Compared to FIG. 9, the interlayer with a composition Al_{w}Ga_{1-w}N, the first passivation layer with a composition Al_{z}Ga_{1-z}N, and the barrier layer with a composition AlₓGa₁₋ₓN become one barrier layer 1135, with a composition Al_{0.3}Ga_{0.7}N where w, x, and z are all equal to 0.3. The in-situ passivation layer 1138 is a SiN layer where y=0.

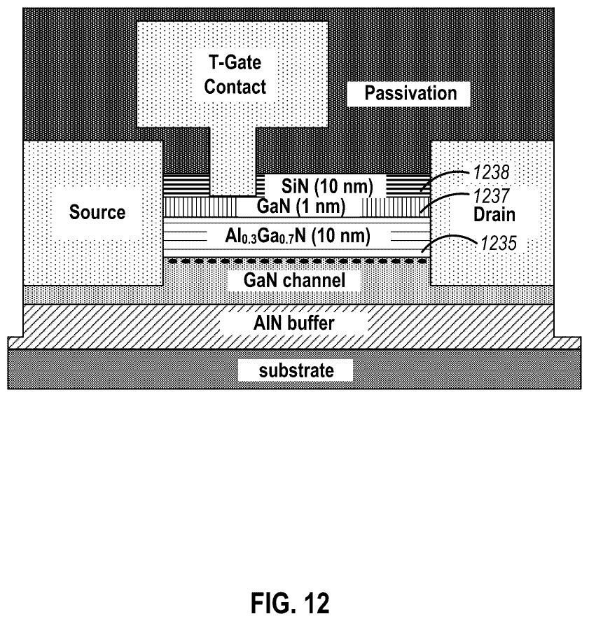

FIG. 12 illustrates yet another example variation of the heterostructure device in FIG. 9 according to embodiments of the disclosure. The device 1200 is similar to the device 600 in FIG. 6. Compared to FIG. 9, the interlayer with a composition Al_{w}Ga_{1-w}N and the barrier layer with a composition AlₓGa₁₋ₓN become one barrier layer 1235 with a composition Al_{0.3}Ga_{0.7}N, where w and x are both equal to 0.3. Corresponding to the first passivation layer 937 with a composition Al_{z}Ga_{1-z}N, the first passivation layer 1237 is a GaN layer where z=0. Corresponding to the in-situ passivation layer 938 with a composition Al_{y}Si_{1-y}N, the in-situ passivation layer 1238 is a SiN layer where y=0.

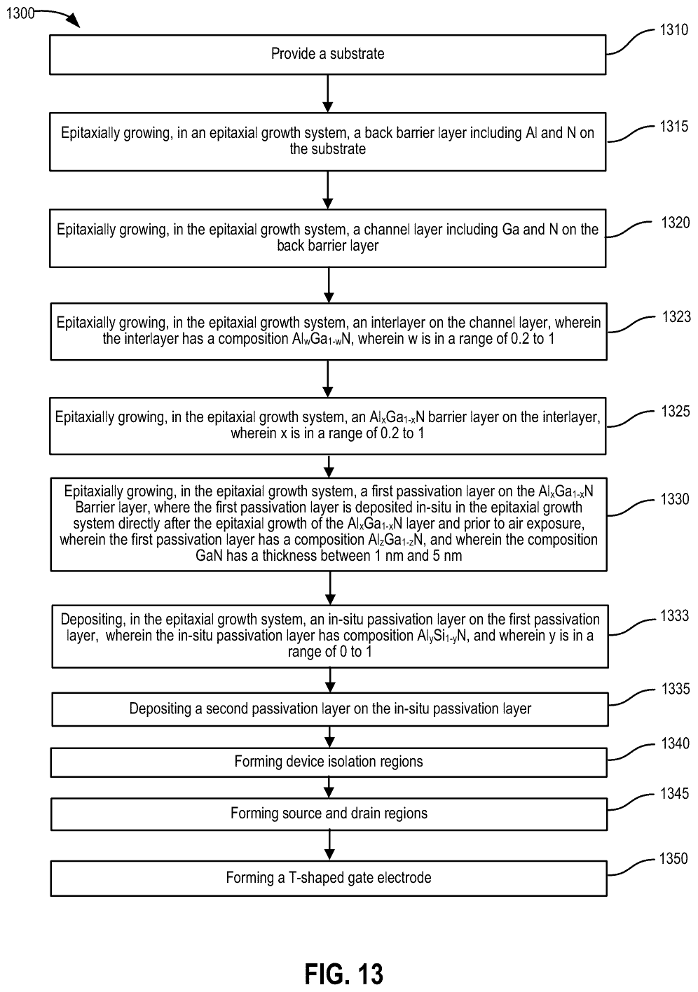

FIG. 13 illustrates a simplified flowchart 1300 illustrating a method for fabricating the heterostructure device illustrated in FIG. 9, according to an embodiment of the disclosure. The description provided in relation to the method illustrated in FIG. 5 is applicable to the method illustrated in FIG. 13 as appropriate, both of which are a passivation-first process. Steps 1310-1320 are similar to steps 510-520. However, the method illustrated in FIG. 13 includes epitaxially growing an interlayer with a composition Al_{w}Ga_{1-w}N on the channel layer (step 1323), epitaxially growing a barrier layer with a composition AlₓGa₁₋ₓN on the interlayer (step 1325), epitaxially growing a first passivation layer with a composition Al_{z}Ga_{1-z}N on the barrier layer (step 1330), and epitaxially growing an in-situ passivation layer with a composition Al_{y}Si_{1-y}N on the first passivation layer (step 1333). Steps 1335-1350 are similar to steps 535-550. In some examples, the in-situ passivation layer is permanent. In some examples, the in-situ passivation layer can be removed prior to (e.g., right before) processing the wafer or at some point during the processing of the wafer in the passivation-first process.

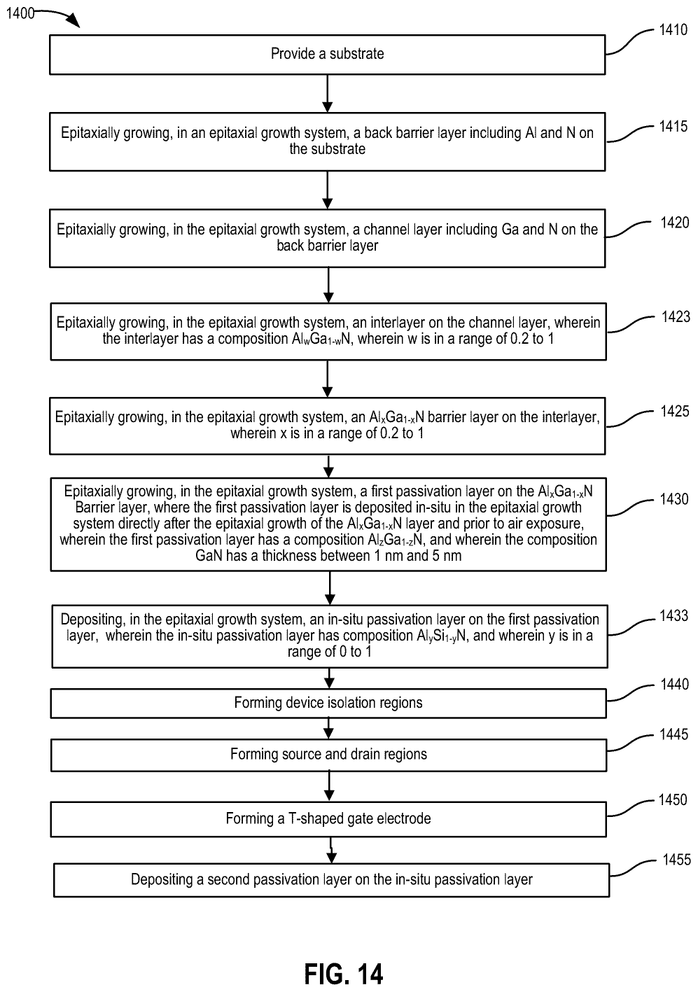

FIG. 14 illustrates a simplified flowchart 1400 illustrating another method for fabricating the heterostructure device illustrated in FIG. 9, according to an embodiment of the disclosure. The description provided in relation to the method illustrated in FIG. 3 is applicable to the method illustrated in FIG. 14 as appropriate, both of which are a passivation-last process.

Steps 1410-1420 are similar to steps 310-320. However, the method illustrated in FIG. 14 includes epitaxially growing an interlayer with a composition Al_{w}Ga_{1-w}N on the channel layer (step 1423), epitaxially growing a barrier layer with a composition AlₓGa₁₋ₓN on the interlayer (step 1425), epitaxially growing a first passivation layer with a composition Al_{z}Ga_{1-z}N on the barrier layer (step 1430), and epitaxially growing an in-situ passivation layer with a composition Al_{y}Si_{1-y}N on the first passivation layer (step 1433). Steps 1440-1455 are similar to steps 340-355. In some examples, the in-situ passivation layer is permanent. In some examples, the in-situ passivation layer can be removed prior to (e.g., right before) processing the wafer or at some point during the processing of the wafer in a passivation-last process.

One of ordinary skill in the art will appreciate that other modifications to the apparatuses and methods of the present disclosure may be made for implementing various applications of the current collapse reduction using AlN back barrier and in-situ two step passivation without departing from the scope of the present disclosure.

The examples and embodiments described herein are for illustrative purposes only.

Various modifications or changes in light thereof will be apparent to persons skilled in the art. These are to be included within the spirit and purview of this application, and the scope of the appended claims which follow.

What is claimed is:

1. A high electron mobility transistor (HEMT) comprising:
a back barrier layer including Al and N on a substrate;
a channel layer including Ga and N on the back barrier layer;
an interlayer on the channel layer, wherein the interlayer has a composition Al_{w}Ga_{1-w}N, wherein w is in a range of 0.2 and 1, and wherein the interlayer and the channel layer are arranged to form a two-dimensional electron gas (2DEG) channel at an interface of the interlayer and the channel layer;
an AlₓGa₁₋ₓN barrier layer on the interlayer, wherein x is in a range of 0.2 to 1;
a first passivation layer on the AlₓGa₁₋ₓN barrier layer, wherein the first passivation layer has a composition Al_{z}Ga_{1-z}N, wherein z is in a range of 0 to 1, wherein a thickness of the first passivation layer is between about 0.5 nm and about 5 nm;
an in-situ passivation layer on the first passivation layer, wherein the in-situ passivation layer has a composition Al_{y}Si_{1-y}N, wherein y is in a range of 0 to 1, wherein a thickness of the in-situ passivation layer is between about 0 nm and about 20 nm;
a drain ohmic contact coupled to the channel layer at a first end of the 2DEG channel;
a source ohmic contact coupled to the channel layer at a second end of the 2DEG channel opposite the first end of the channel;
a T-shaped gate electrode at a location on a surface between the drain ohmic contact and the source ohmic contact, the T-shaped gate electrode including a neck portion that extends a first distance above the surface to a head portion of the T-shaped gate electrode; and
a second passivation layer on the in-situ passivation layer and continuously extending from an upper surface of the drain ohmic contact to an upper surface of the source ohmic contact to cover the surface and to cover at least one portion of the T-shaped gate electrode.

2. The HEMT of claim 1, further comprising a recessed region through the in-situ passivation layer, wherein the recessed region is used to form a gate contact to the first passivation layer.

3. The HEMT of claim 1, further comprising a third passivation layer that extends continuously from the upper surface of the drain ohmic contact to the upper surface of the source ohmic contact to cover the surface and to cover the T-shaped gate electrode.

4. The HEMT of claim 3, further comprising:
a gate electrode recess in an uppermost surface of the head portion of the T-shaped gate electrode; and
a passivation layer recess in an upper surface of the third passivation layer above the gate electrode recess, the passivation layer recess having a passivation layer recess shape that conforms to a shape of the gate electrode recess.

5. The HEMT of claim 3, further comprising a source-connected metal field plate deposited on a top surface of the third passivation layer and located between a source edge of the T-shaped gate electrode and an edge of the drain ohmic contact.

6. The HEMT of claim 1, wherein the channel layer has a thickness less than 500 nm.

7. The HEMT of claim 1, wherein the at least one portion of the T-shaped gate electrode comprises a bottom surface of the head portion of the T-shaped gate electrode and the neck portion.

8. The HEMT of claim 1, wherein the second passivation layer comprises silicon nitride (SiN).

9. A method of fabricating a gallium nitride (GaN) based high electron mobility transistor (HEMT), the method comprising:
providing a substrate;
epitaxially growing, in an epitaxial growth system, a back barrier layer including Al and N on the substrate;
epitaxially growing, in the epitaxial growth system, a channel layer including Ga and N on the back barrier layer;
epitaxially growing, in the epitaxial growth system, an interlayer on the channel layer, wherein the interlayer has a composition Al_{w}Ga_{1-w}N, wherein w is in a range of 0.2 and 1, and wherein the interlayer and the channel layer are arranged to form a two-dimensional electron gas (2DEG) channel at an interface of the interlayer and the channel layer;
epitaxially growing, in the epitaxial growth system, an AlₓGa₁₋ₓN barrier layer on the interlayer, wherein x is in a range of 0.2 to 1;
epitaxially growing, in the epitaxial growth system, a first passivation layer on the AlₓGa₁₋ₓN barrier layer, wherein the first passivation layer is deposited in-situ in the epitaxial growth system directly after the epitaxial growth of the AlₓGa₁₋ₓN barrier layer and prior to air exposure, wherein the first passivation layer has a composition Al_{z}Ga_{1-z}N, wherein z is in a range of 0 to 1, wherein a thickness of the first passivation layer is between about 1 nm and about 5 nm;
depositing, in the epitaxial growth system, an in-situ passivation layer on the first passivation layer, wherein the in-situ passivation layer has a composition Al_{y}Si_{1-y}N, and wherein y is in a range of 0 to 1;
depositing a second passivation layer on the in-situ passivation layer;
forming device isolation regions;
forming a drain ohmic contact coupled to the channel layer at a first end of the 2DEG channel;
forming a source ohmic contact coupled to the channel layer at a second end of the 2DEG channel opposite the first end of the channel; and
forming a T-shaped gate electrode at a location on a surface between the drain ohmic contact and the source ohmic contact, the T-shaped gate electrode recessed through the second passivation layer and in-situ passivation layer and contacting the first passivation layer, wherein the T-shaped gate electrode includes a neck portion that extends a first distance above the surface to a head portion of the T-shaped gate electrode.

10. The method of claim 9, further comprising, prior to depositing a second passivation layer, removing the in-situ passivation layer prior to depositing the second passivation layer.

11. The method of claim 9, further comprising:
depositing a third passivation layer to cover the surface between the drain ohmic contact and the source ohmic contact and cover the T-shaped gate electrode.

12. The method of claim 11, further comprising depositing a source-connected metal field plate on a top surface of the third passivation layer and located between a source edge of the T-shaped gate electrode and an edge of the drain ohmic contact.

13. The method of claim 9, further comprising forming device isolation regions prior to deposition of the second passivation layer.

14. The method of claim 9, wherein depositing the second passivation layer is performed using a low pressure chemical vapor deposition (LPCVD) process.

15. The method of claim 9, wherein depositing the second passivation layer is performed using a plasma enhanced chemical vapor deposition (PECVD) process.

16. The method of claim 9, wherein forming the drain ohmic contact and forming the source ohmic contact comprises:
depositing drain and source metals on a surface of the first passivation layer; and
annealing to fuse the drain and source metals to form contacts to the 2DEG channel.

17. The method of claim 9, wherein forming the drain ohmic contact and forming the source ohmic contact comprises:
forming drain and source recessed regions by dry etching; and
growing n-type doped GaN to form contacts to the 2DEG channel.

18. A method of fabricating a gallium nitride (GaN) based high electron mobility transistor (HEMT), the method comprising:
providing a substrate;
epitaxially growing, in an epitaxial growth system, a back barrier layer including Al and N on the substrate;
epitaxially growing, in the epitaxial growth system, a channel layer including Ga and N on the back barrier layer;
epitaxially growing, in the epitaxial growth system, an interlayer on the channel layer, wherein the interlayer has a composition Al_{w}Ga_{1-w}N, wherein w is in a range of 0.2 and 1, and wherein the interlayer and the channel layer are arranged to form a two-dimensional electron gas (2DEG) channel at an interface of the interlayer and the channel layer;
epitaxially growing, in the epitaxial growth system, an AlₓGa₁₋ₓN barrier layer on the interlayer, wherein x is in a range of 0.2 to 1;
epitaxially growing, in the epitaxial growth system, a first passivation layer on the AlₓGa₁₋ₓN barrier layer, wherein the first passivation layer is deposited in-situ in the epitaxial growth system directly after the epitaxial growth of the AlₓGa₁₋ₓN barrier layer and prior to air exposure, wherein the first passivation layer has a composition Al_{z}Ga_{1-z}N, wherein z is in a range of 0 to 1, wherein a thickness of the first passivation layer is between about 1 nm and about 5 nm;
depositing, in the epitaxial growth system, an in-situ passivation layer on the first passivation layer, wherein the in-situ passivation layer has a composition Al_{y}Si_{1-y}N, and wherein y is in a range of 0 to 1;
forming device isolation regions;
forming a drain ohmic contact coupled to the channel layer at a first end of the 2DEG channel;
forming a source ohmic contact coupled to the channel layer at a second end of the 2DEG channel opposite the first end of the channel; and
forming a T-shaped gate electrode at a location on a surface between the drain ohmic contact and the source ohmic contact, the T-shaped gate electrode contacting the first passivation layer, wherein the T-shaped gate electrode includes a neck portion that extends a first distance above the surface to a head portion of the T-shaped gate electrode; and
depositing a second passivation layer that continuously extends from an upper surface of the drain ohmic contact to an upper surface of the source ohmic contact to cover the surface and to cover the T-shaped gate electrode.

19. The method of claim 18, further comprising, prior to depositing the second passivation layer, removing the in-situ passivation layer prior to depositing the second passivation layer.

20. The method of claim 18, further comprising depositing a source-connected metal field plate on a top surface of the second passivation layer and located between a source edge of the T-shaped gate electrode and an edge of the drain ohmic contact.

21. The method of claim 18, wherein depositing the second passivation layer is performed using a plasma enhanced chemical vapor deposition (PECVD) process.

22. The method of claim 18, wherein forming the drain ohmic contact and forming the source ohmic contact comprises:
depositing drain and source metals on a surface of the first passivation layer; and
annealing to fuse the drain and source metals to form contacts to the 2DEG channel.

23. The method of claim 18, wherein forming the drain ohmic contact and forming the source ohmic contact comprises:
forming drain and source recessed regions by dry etching; and
growing n-type doped GaN to form contacts to the 2DEG channel.

24. The method of claim 18, further comprising forming the drain ohmic contact and the source ohmic contact prior to forming the device isolation regions.
